(19) United States
(12) Patent Application Publication
(10) Pub. No.: US 2024/0188388 A1
(43) Pub. Date: Jun. 6, 2024

(54) DISPLAY PANEL AND DISPLAY DEVICE INCLUDING THE SAME

(71) Applicant: Samsung Display Co., Ltd., Yongin-Si (KR)

(72) Inventors: SIJIN Sung, Yongin-si (KR); Shogo Nishizaki, Yongin-si (KR); Jaehyun Kim, Yongin-si (KR); Illsoo Park, Yongin-si (KR)

(21) Appl. No.: 18/242,026

(22) Filed: Sep. 5, 2023

(30) Foreign Application Priority Data
Dec. 5, 2022 (KR) 10-2022-0168058

(51) Int. Cl. H10K 59/80; H10K 59/122

(52) U.S. Cl. CPC H10K 59/873; H10K 59/122; H10K 2102/351

(57) ABSTRACT

A display panel includes a display element layer including a pixel defining film having a pixel opening defined therein and a light emitting element. An encapsulation layer is disposed on the display element layer. The encapsulation layer includes a first inorganic encapsulation film. An organic encapsulation film is disposed on the first inorganic encapsulation film. A second inorganic encapsulation film is disposed on the organic encapsulation film. The second inorganic encapsulation film has a refractive index in a range of about 1.89 to about 2.20.

### CROSS-REFERENCE TO RELATED APPLICATIONS

This application claims priority under 35 U.S.C. § 119 to Korean Patent Application No. 10-2022-0168058, filed on Dec. 5, 2022 in the Korean Intellectual Property Office, the disclosure of which is incorporated by reference in its entirety herein.

### 1. TECHNICAL FIELD

The present disclosure herein relates to a display panel including an inorganic encapsulation film having a relatively high refractive index, and a display device including the same.

### 2. DISCUSSION OF RELATED ART

Display devices have been applied to numerous types of electronic devices to provide image information. A self-luminous display devices using organic electroluminescent materials or quantum dot light emitting materials has been developed. Self-luminous display devices include a light emitting element. The light emitting element is vulnerable to environmental contaminants, such as oxygen and moisture. Accordingly, various types of techniques for encapsulating the light emitting element have been developed. For example, a technique of disposing an encapsulation layer on a light emitting element to block penetration paths of air, moisture, and the like is under development. The encapsulation layer may include a structure in which an inorganic film including inorganic matter and an organic film including organic matter are alternately stacked on each other. However, a refractive index of the encapsulation layer may decrease the display lifetime of display devices.

### SUMMARY

The present disclosure provides a display panel having an increased display lifetime and a display device including the display panel.

According to an embodiment of the present inventive concept, a display panel includes a display element layer including a pixel defining film having a pixel opening defined therein and a light emitting element. An encapsulation layer is disposed on the display element layer. The encapsulation layer includes a first inorganic encapsulation film. An organic encapsulation film is disposed on the first inorganic encapsulation film. A second inorganic encapsulation film is disposed on the organic encapsulation film. The second inorganic encapsulation film has a refractive index in a range of about 1.89 to about 2.20.

In an embodiment, the second inorganic encapsulation film may include silicon nitride.

In an embodiment, the first inorganic encapsulation film may include at least one compound selected from silicon nitride, silicon oxynitride, silicon oxide, titanium oxide, and aluminum oxide.

In an embodiment, the second inorganic encapsulation film may have a thickness in a range of about 6000 Å to about 8000 Å.

In an embodiment, the first inorganic encapsulation film may have a thickness in a range of about 10600 Å to about 11600 Å.

In an embodiment, the organic encapsulation film may have a thickness in a range of about 79000 Å to about 81000 Å.

In an embodiment, a thickness of the organic encapsulation film may be greater than a thickness of the first inorganic encapsulation film and the second inorganic encapsulation film.

In an embodiment, the first inorganic encapsulation film may include a first sub-inorganic encapsulation layer, a second sub-inorganic encapsulation layer, and a third sub-inorganic encapsulation layer that are sequentially stacked. A thickness of the second sub-inorganic encapsulation layer may be greater than thicknesses of the first sub-inorganic encapsulation layer and the third sub-inorganic encapsulation layer.

In an embodiment, the encapsulation layer may cover the display element layer.

In an embodiment, the light emitting element may include a first electrode exposed in the pixel opening, a second electrode disposed on the first electrode, and an emission layer disposed between the first electrode and the second electrode, and the light emitting element may emit blue light or white light.

In an embodiment, the emission layer may emit thermally activated delayed fluorescence or phosphorescence.

In an embodiment, the light emitting element may further include a hole transport region disposed between the first electrode and the emission layer. An electron transport region is disposed between the emission layer and the second electrode.

According to an embodiment of the present inventive concept, a display device includes a display panel. A protection member is disposed on the display pane. The display panel includes a display element layer including a pixel defining film having a pixel opening defined therein, and a light emitting element. An encapsulation layer is disposed on the display element layer. The encapsulation layer includes a first inorganic encapsulation film, an organic encapsulation film disposed on the first inorganic encapsulation film, and a second inorganic encapsulation film disposed on the organic encapsulation film. The second inorganic encapsulation film has a refractive index in a range of about 1.89 to about 2.20.

In an embodiment, the second inorganic encapsulation film may include silicon nitride.

In an embodiment, the display device may not include a polarizing plate.

In an embodiment, the first inorganic encapsulation film may include at least one compound selected from silicon nitride, silicon oxynitride, silicon oxide, titanium oxide, and aluminum oxide.

In an embodiment, the second inorganic encapsulation film may have a thickness in a range of about 6000 Å to about 8000 Å.

In an embodiment, the first inorganic encapsulation film may have a thickness in a range of about 10600 Å to about 11600 Å.

In an embodiment, the organic encapsulation film may have a thickness in a range of about 79000 Å to about 81000 Å.

In an embodiment, the display element layer may include a first light emitting element, a second light emitting element, and a third light emitting element that are spaced apart from each other in a first direction perpendicular to a thickness direction. The first light emitting element may emit red light, the second light emitting element may emit green light, and the third light emitting element may emit blue light.

### BRIEF DESCRIPTION OF THE DRAWINGS

The accompanying drawings are included to provide a further understanding of embodiments of the present inventive concept, and are incorporated in and constitute a part of this specification. The drawings illustrate non-limiting embodiments of the present inventive concept and, together with the description, serve to explain principles of the present inventive concept. In the drawings:

FIG. 1 is a perspective view showing a display device according to an embodiment of the present inventive concept;

FIG. 2 is a cross-sectional view showing a portion corresponding to line I-I of FIG. 1 according to an embodiment of the present inventive concept;

FIG. 3 is an enlarged cross-sectional view showing a display panel taken from area XX′ of FIG. 2 according to an embodiment of the present inventive concept;

FIG. 4 is a cross-sectional view showing a display panel according to an embodiment of the present inventive concept;

FIG. 5 is a cross-sectional view showing a portion of a display panel according to an embodiment of the present inventive concept;

FIG. 6 is a graph showing light transmittance over time in display panels of Comparative Examples;

FIG. 7 is a graph showing light transmittance over time in display panels of Examples according to an embodiment of the present inventive concept;

FIG. 8 is a graph showing light efficiency over time in display panels of Comparative Examples and Examples according to an embodiment of the present inventive concept;

FIG. 9 is a graph showing light efficiency over time in display panels of Comparative Examples and Examples according to an embodiment of the present inventive concept;

FIG. 10 is a graph showing color coordinates in display panels of Comparative Examples;

FIG. 11 is a graph showing color coordinates in display panels of Examples according to an embodiment of the present inventive concept;

FIG. 12 is a graph showing light efficiency over time in display panels of Comparative Examples and Examples according to an embodiment of the present inventive concept;

FIG. 13 is a graph showing light efficiency over time in display panels of Comparative Examples and Examples according to an embodiment of the present inventive concept;

FIG. 14 is a graph showing color coordinates in display panels of Comparative Examples;

FIG. 15 is a graph showing color coordinates in display panels of Examples according to an embodiment of the present inventive concept;

FIG. 16 is a graph showing light efficiency over time in display panels of Comparative Examples and Examples according to an embodiment of the present inventive concept;

FIG. 17A is a graph showing transmittance versus wavelength in display panels of Comparative Examples;

FIG. 17B is a graph showing transmittance versus wavelength in display panels of Comparative Examples;

FIG. 17C is a graph showing transmittance versus wavelength in display panels of Comparative Examples;

FIG. 18A is a graph showing transmittance versus wavelength in display panels of Examples according to an embodiment of the present inventive concept;

FIG. 18B is a graph showing transmittance versus wavelength in display panels of Examples according to an embodiment of the present inventive concept; and

FIG. 18C is a graph showing transmittance versus wavelength in display panels of Examples according to an embodiment of the present inventive concept.

### DETAILED DESCRIPTION OF EMBODIMENTS

The present disclosure may be modified in many alternate forms, and thus non-limiting embodiments will be shown in the drawings and described in detail. It should be understood, however, that it is not intended to limit the present disclosure to the particular forms disclosed, but rather, is intended to cover all modifications, equivalents, and alternatives falling within the spirit and scope of the present disclosure.

As used herein, when an element (or a region, a layer, a portion, and the like) is referred to as being “on,” “connected to,” or “coupled to” another element, it indicates that the element may be directly disposed on/connected to/coupled to the other element, or that a third element may be disposed therebetween. When an element (or a region, a layer, a portion, and the like) is referred to as being “directly on,” “directly connected to,” or “directly coupled to” another element no intervening third element may be disposed therebetween.

Like reference numerals refer to like elements. In addition, in the drawings, the thickness, the ratio, and the dimensions of elements are exaggerated for an effective description of technical contents. The term “and/or,” includes all combinations of one or more of which associated configurations may define.

It will be understood that, although the terms first, second, etc. may be used herein to describe various elements, these elements should not necessarily be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense. Also, terms, such as those defined in commonly used dictionaries, should be interpreted as having a meaning that is consistent with their meaning in the context of the relevant art and should not be interpreted in an idealized or overly formal sense unless expressly so defined herein.

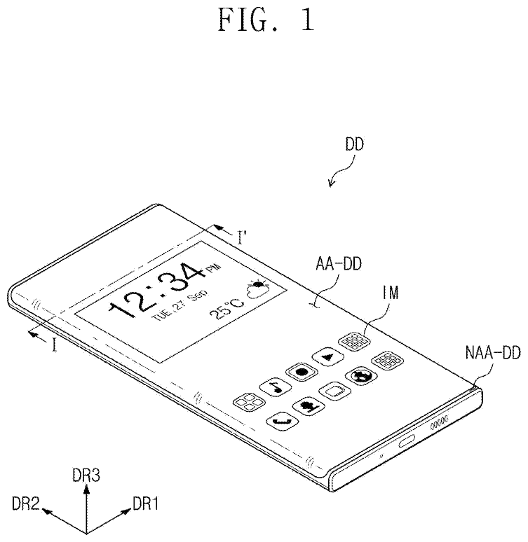

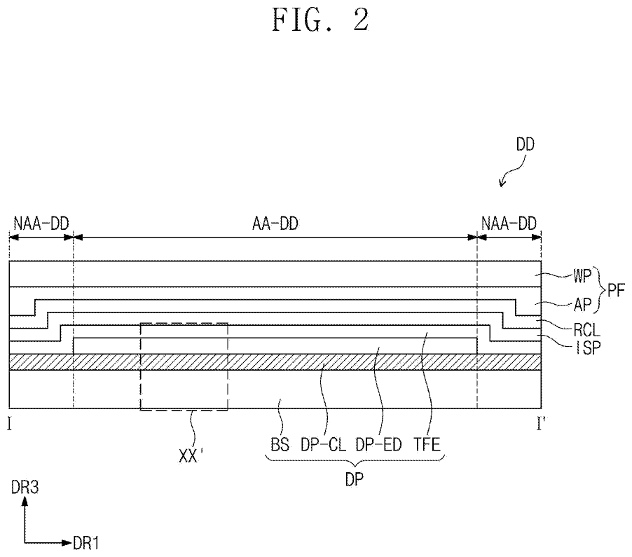

Hereinafter, a display panel according to an embodiment of the present inventive concept and a display device including the same will be described with reference to the accompanying drawings. FIG. 1 is a perspective view showing a display device DD of an embodiment. FIG. 2 is a cross-sectional view showing a portion corresponding to line I-I′ of FIG. 1. In addition, FIG. 2 is a cross-sectional view of a display device DD according to an embodiment of the present inventive concept.

A display device DD may be a device activated according to electrical signals. For example, in an embodiment the display device DD may be a mobile phone, a tablet, a car navigation system, a game console, or a wearable device. However, embodiments of the present inventive concept are not necessarily limited thereto. In FIG. 1, a mobile phone is shown to be the display device DD as an example.

The display device DD may display an image IM through an active region AA-DD. The active region AA-DD may include a plane defined by a first directional axis DR1 and a second directional axis DR2. The active region AA-DD may further include a curved surface bent from one side of the plane defined by the first directional axis DR1 and the second directional axis DR2. In an embodiment shown in FIG. 1, the display device DD includes two curved surfaces each bent from both sides of the plane defined by the first directional axis DR1 and the second directional axis DR2. However, embodiments of the present disclosure are not necessarily limited thereto, and the shape of the active region AA-DD may vary. For example, in some embodiments the active region AA-DD may include only the plane or the active region AA-DD may further include curved surfaces each bent from at least two sides of the plane (e.g., four curved surfaces each bent from four sides of the plane).

The peripheral region NAA-DD is adjacent to the active region AA-DD. The peripheral region NAA-DD may surround the active region AA-DD (e.g., in the first and/or second directions DR1, DR2). Accordingly, the shape of the active region AA-DD may be substantially defined by the peripheral region NAA-DD. However, embodiments of the present inventive concept are not necessarily limited thereto, and the peripheral region NAA-DD may be disposed adjacent to only one side of the active region AA-DD, or may be omitted altogether in some embodiments. The display device DD according to an embodiment may include various shapes of active regions and is not necessarily limited to any one embodiment.

FIG. 1 and the following drawings show the first to third directional axes DR1 to DR3, and directions indicated by the first to third directional axes DR1, DR2, and DR3 described herein are relative concepts, and may thus be changed to other directions. In addition, the directions indicated by the first to third directional axes DR1, DR2, and DR3 may be described as first to third directions, and the same reference numerals may be used. The first directional axis DR1 and the second directional axis DR2 herein may be perpendicular to each other, and a third directional axis DR3 may be a normal direction to a plane defined by the first directional axis DR1 and the second directional axis DR2.

A thickness direction of the display device DD may be parallel to the third directional axis DR3 which is a normal direction with respect to a plane defined by the first directional axis DR1 and the second directional axis DR2. As described herein, a front surface (e.g., an upper surface) and a rear surface (e.g., a lower surface) of members constituting the display device DD may be defined with respect to the third directional axis DR3. As used herein, upper and lower sides may be defined with respect to third directional axis DR3. The upper side indicates a direction adjacent to the active region AA-DD where the image IM is displayed, and the lower side indicates a direction away from the active region AA-DD.

As used herein, when a component is “directly disposed/directly formed” on another component, it indicates that a third component is not disposed between one component and another component. For example, when a component is “directly placed/directly formed” on another component, it indicates that a component is in “direct contact” with another component.

Referring to FIG. 2, the display device DD according to an embodiment may include a display panel DP and a protection member PF disposed on the display panel. In addition, the display device DD may further include an input sensing layer ISP disposed between the display panel DP and the protection member PF (e.g., in the third direction DR3).

The protection member PF may include an adhesive layer AP and a window WP. The window WP and the input sensing layer ISP may be bonded to each other through the adhesive layer AP. In an embodiment, the adhesive layer AP may include a typical adhesive such as a pressure sensitive adhesive (PSA), an optically clear adhesive (OCA), an optical clear resin (OCR), and the like. However, embodiments of the present inventive concept are not necessarily limited thereto and the composition of the adhesive layer AP may vary. Additionally, in an embodiment the adhesive layer AP may be omitted altogether.

The window WP may include an optically transparent insulating material. In an embodiment, the window WP may be a glass substrate or a polymer substrate. For example, in an embodiment the window WP may be a tempered glass substrate subjected to a strengthening treatment. Alternatively, the window WP may be formed of polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof. However, embodiments of the present inventive concept are not necessarily limited thereto, and the material included in the window WP may vary.

In an embodiment, the protection member PF may further include at least one functional layer provided on the window WP. For example, in some embodiments the functional layer may be a hard coating layer, an anti-fingerprint coating layer, and the like. However, embodiments of the present inventive concept are not necessarily limited thereto.

The input sensing layer ISP may be disposed on the display panel DP (e.g., in the third direction DR3). The input sensing layer ISP may detect external inputs applied from the outside. The external inputs may be user inputs. For example, in an embodiment the user inputs may include various types of external inputs such as a body part of users in contact with, or in proximity to, the display device DD, light, heat, pen, or pressure. However, embodiments of the present inventive concept are not necessarily limited thereto.

For example, in an embodiment the input sensing layer ISP may be formed on the display panel DP through a roll-to-roll process. In this embodiment, the input sensing layer ISP may be directly disposed on the display panel DP. Being directly disposed may indicate that a third component is not disposed between the input sensing layer ISP and the display panel DP (e.g., in the third direction DR3). For example, a separate adhesive member may not be disposed between the input sensing layer ISP and the display panel DP (e.g., in the third direction DR3). Alternatively, the input sensing layer ISP may be bonded to the display panel DP through an adhesive member. The adhesive member may include a general adhesive or a gluing agent.

In addition, the display device DD may further include an optical layer RCL disposed between the input sensing layer ISP and the protection member PF (e.g., in the third direction DR3). The optical layer RCL may be an anti-reflection layer reducing reflectance by external light. In an embodiment, the optical layer RCL may be formed on the input sensing layer ISP through a roll-to-roll process. The optical layer RCL may include a polarizing plate or a color filter layer. In an embodiment in which the optical layer RCL includes a color filter layer, the color filter layer may include a plurality of color filters disposed in a predetermined arrangement. For example, the color filters may be arranged in consideration of light emitting colors of pixels included in the display panel DP. In addition, the optical layer RCL may further include a black matrix adjacent to the color filters. In some embodiments, the optical layer RCL may be omitted altogether.

The display panel DP may be configured to generate images. In an embodiment, the display panel DP may be a light emitting display panel, and for example, the display panel DP may be an organic light emitting display panel, an inorganic light emitting display panel, a quantum dot display panel, a micro LED display panel, or a nano LED display panel. The display panel DP may be referred to as a display layer. The display panel DP may include a base layer BS, a circuit layer DP-CL, a display element layer DP-ED, and an encapsulation layer TFE.

The base layer BS may be a member providing a base surface in which the circuit layer DP-CL is disposed thereon (e.g., in the third direction DR3). The base layer BS may be a rigid substrate, or a flexible substrate that is bendable, foldable, rollable, or the like. In an embodiment, the base layer BS may be a glass substrate, a metal substrate, or a polymer substrate. However, embodiments of the present inventive concept are not necessarily limited thereto. For example, in some embodiments the base layer BS may be an inorganic layer, an organic layer, or a composite material layer.

The circuit layer DP-CL may be disposed on the base layer BS (e.g., in the third direction DR3). In an embodiment, the circuit layer DP-CL may include an insulating layer, a semiconductor pattern, a conductive pattern, a signal line, and the like. In an embodiment, the insulating layer, the semiconductor layer, and the conductive layer may be formed on the base layer BS through methods such as coating or vapor deposition, and then selectively patterned through multiple times of a photolithography process. Thereafter, the semiconductor pattern, the conductive pattern, and the signal line included in the circuit layer DP-CL may be formed.

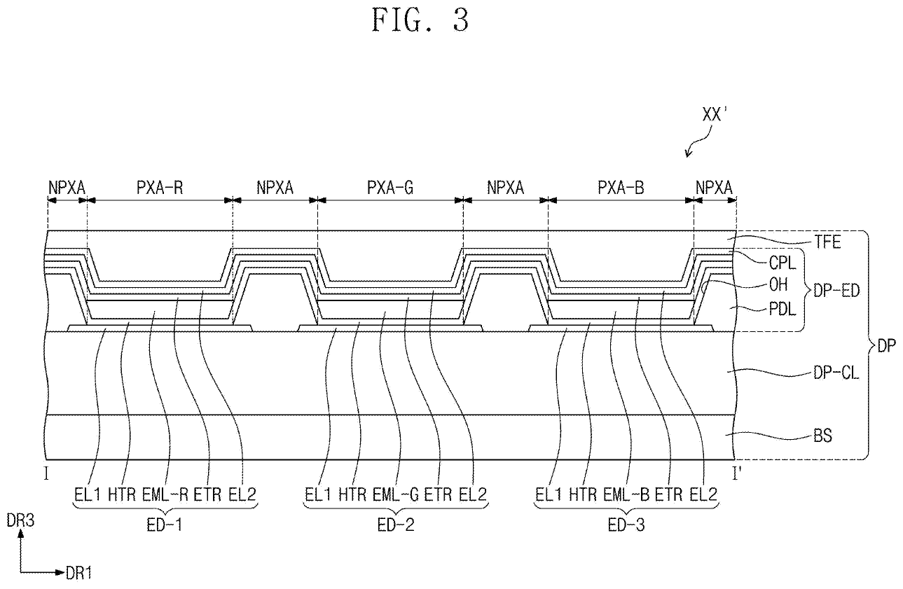

The display element layer DP-ED may be disposed on the circuit layer DP-CL (e.g., in the third direction DR3). The display element layer DP-ED may include a pixel defining film PDL and first to third light emitting elements ED-1, ED-2, and ED-3 (FIG. 3), which will be described later. For example, in an embodiment the display element layer DP-ED may include organic light emitting materials, inorganic light emitting materials, organic-inorganic light emitting materials, quantum dots, quantum rods, micro LEDs, or nano LEDs. However, embodiments of the present inventive concept are not necessarily limited thereto.

The encapsulation layer TFE may be disposed on the display element layer DP-ED. For example, in an embodiment the encapsulation layer TFE may be disposed on an upper surface and lateral sides of the display element layer DP-ED. The encapsulation layer TFE may serve to protect the light emitting element layer DP-ED from moisture, oxygen, and foreign substances such as dust particles.

FIG. 3 is an enlarged cross-sectional view showing region XX′ of FIG. 2. FIG. 3 may be a detailed cross-sectional view of the display panel DP of FIG. 2.

The base layer BS may include a single- or multi-layered structure. For example, in an embodiment the base layer BS may include a first synthetic resin layer, a multi-layered or single-layered intermediate layer, and a second synthetic resin layer, which are sequentially stacked (e.g., in the third direction DR3). The intermediate layer may be referred to as a base barrier layer. In an embodiment, the intermediate layer may include a silicon oxide (SiOx) layer and an amorphous silicon (a-Si) layer disposed on the silicon oxide layer. However, embodiments of the present disclosure are not necessarily limited thereto. For example, in an embodiment the intermediate layer may include at least one of a silicon oxide layer, a silicon nitride layer, a silicon oxynitride layer, or an amorphous silicon layer.

In an embodiment, the first and second synthetic resin layers may each include a polyimide-based resin. In addition, the first and second synthetic resin layers may each include at least one material selected from an acrylic-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, a “material-based” resin may be considered as including a functional group of the “material”.

The circuit layer DP-CL may be disposed on the base layer BS, and the circuit layer DP-CL may include a plurality of transistors. In an embodiment, the transistors may each include a control electrode, an input electrode, and an output electrode. For example, the circuit layer DP-CL may include a switching transistor and a driving transistor for driving the plurality of light emitting elements ED-1, ED-2 and ED-3 of the display element layer DP-ED.

The display element layer DP-ED may include a pixel defining film PDL and first to third light emitting elements ED-1, ED-2, and ED-3. The pixel defining film PDL may have a pixel opening OH defined therein. For example, the pixel defining film PDL may include an organic light blocking material or an inorganic light blocking material, both including a black pigment or a black dye.

The display panel DP may be divided into a non-light emitting region NPXA and a plurality of light emitting regions, such as first to third light emitting regions PXA-R, PXA-G, and PXA-B. The first to third light emitting regions PXA-R, PXA-G, and PXA-B may each be a region emitting light generated from each of the first to third light emitting elements ED-1, ED-2, and ED-3. The first to third light emitting regions PXA-R, PXA-G, and PXA-B may be spaced apart from each other when viewed on a plane. While an embodiment of FIG. 3 shows three light emitting regions and three light emitting elements, embodiments of the present inventive concept are not necessarily limited thereto and the numbers of the light emitting regions and light emitting elements may vary.

The first to third light emitting regions PXA-R. PXA-G, and PXA-B may each be an region separated by the pixel defining films PDL. The non-light emitting regions NPXA may be regions between adjacent light emitting regions, such as the first to third light emitting regions PXA-R, PXA-G, and PXA-B, and may correspond to the pixel defining film PDL. The light emitting regions PXA-R, PXA-G, and PXA-B may each correspond to a pixel. The pixel defining film PDL may separate the first to third light emitting elements ED-1, ED-2, and ED-3. Emission layers EML-R, EML-G, and EML-B of the light emitting elements ED-1, ED-2 and ED-3 may be disposed and separated in the pixel opening OH defined by the pixel defining film PDL.

The light emitting regions, such as the first to third light emitting regions PXA-R, PXA-G, and PXA-B, may be divided into a plurality of groups according to the color of light generated from the light emitting elements, such as the first to third light emitting elements ED-1, ED-2 and ED-3. In the display device DD of an embodiment shown in FIG. 3, three light emitting regions PXA-R, PXA-G, and PXA-B, which emit red light, green light, and blue light, are shown as an example. For example, the display device DD of an embodiment may include a red light emitting region PXA-R, a green light emitting region PXA-G, and a blue light emitting region PXA-B, which are distinct from one another.

The first to third light emitting elements ED-1, ED-2, and ED-3 may be spaced apart in one direction (e.g., the first direction DR1) perpendicular to the thickness direction DR3. The first to third light emitting elements ED-1, ED-2, and ED-3 may emit light in different wavelength ranges. For example, in an embodiment the first light emitting element ED-1 may emit red light, the second light emitting element ED-2 may emit green light, and the third light emitting element ED-3 may emit blue light. The red light emitting region PXA-R, the green light emitting region PXA-G, and the blue light emitting region PXA-B may correspond to the first light emitting element ED-1, the second light emitting element ED-2, and the third light emitting element ED-3, respectively.

However, embodiments of the present inventive concept are not necessarily limited thereto, and the first to third light emitting elements ED-1, ED-2 and ED-3 may emit light in the same wavelength range as each other or emit light in at least one different wavelength range. For example, in an embodiment the first to third light emitting elements ED-1, ED-2, and ED-3 may all emit blue light.

The first to third light emitting elements ED-1, ED-2, and ED-3 may each include a first electrode EL1, a second electrode EL2 disposed on the first electrode EL1, and first to third emission layers EML-R, EML-G, and EML-B disposed between the first electrode EL1 and the second electrode EL2. The first electrode EL1 may be exposed in the pixel opening OH of the pixel defining film PDL. In an embodiment, the pixel opening OH of the pixel defining film PDL may overlap a central portion of the first electrode EL1. However, embodiments of the present inventive concept are not necessarily limited thereto.

In addition, each of the first to third light emitting elements ED-1, ED-2, and ED-3 may further include a hole transport region HTR and an electron transport region ETR. The hole transport region HTR may be disposed between the first electrode EL1 and the first to third emission layers EML-R, EML-G, and EML-B. The electron transport region ETR may be disposed between each of the first to third emission layers EML-R, EML-G, and EML-B and the second electrode EL2, respectively.

FIG. 3 shows an embodiment in which the first to third emission layers EML-R, EML-G, and EML-B of the first to third light emitting elements ED-1, ED-2, and ED-3 are disposed in the pixel opening OH defined in the pixel defining film PDL, and the hole transport region HTR, the electron transport region ETR, and the second electrode EL2 are provided as a common layer throughout the first to third light emitting elements ED-1, ED-2, and ED-3. However, embodiments of the present inventive concept are not necessarily limited thereto, and unlike what is shown in FIG. 3, in an embodiment, the hole transport region HTR and the electron transport region ETR may be provided to be patterned inside the pixel opening OH defined in the pixel defining film PDL. For example, in an embodiment, the hole transport region HTR, the first to third emission layers EML-R, EML-G, and EML-B, and the electron transport region ETR, and the like of the first to third light emitting elements ED-1, ED-2, and ED-3 may be patterned and provided through an inkjet printing method.

In an embodiment, the first electrode EL1 may be an anode or a cathode. However, embodiments of the present inventive concept are not necessarily limited thereto. In addition, the first electrode EL1 may be a pixel electrode. The first electrode EL1 may be a transmissive electrode, a transflective electrode, or a reflective electrode. In an embodiment, the first electrode may include at least one compound selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof. However, embodiments of the present inventive concept are not necessarily limited thereto.

In an embodiment in which the first electrode EL1 is the transmissive electrode, the first electrode EL1 may include a transparent metal oxide such as indium tin oxide (ITO), indium zinc oxide (IZO), zinc oxide (ZnO), and indium tin zinc oxide (ITZO). In an embodiment in which the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). Alternatively, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and the like. For example, the first electrode EL1 may have a three-layer structure of ITO/Ag/ITO. However, embodiments of the present inventive concept are not necessarily limited thereto. In addition, the first electrode EL1 may include the above-described metal materials, a combination of two or more metal materials selected from the above-described metal materials, or oxides of the above-described metal materials. However, embodiments of the present inventive concept are not necessarily limited thereto.

The hole transport region HTR may have a single layer formed of a single material, a single layer formed of a plurality of different materials, or a multilayer structure having a plurality of layers formed of a plurality of different materials. In an embodiment, the hole transport region HTR may include at least one among a hole injection layer HIL, a hole transport layer, and an electron blocking layer. In addition, the hole transport region HTR may further include a light emitting auxiliary layer for compensating a resonance distance according to the wavelength of light emitted from the first to third emission layers EML-R, EML-G, and EML-B.

In an embodiment, the hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h] quinoxaline-2,3,6,7,10,11-hexacarbonitrile (HATCN), and the like.

In addition, in an embodiment the hole transport region HTR may include carbazole-based derivatives such as N-phenyl carbazole and polyvinyl carbazole, fluorene-based derivatives, N,N′-bis(3-methylphenyl)-N, N′-diphenyl-[1, l′-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (DCP), and the like.

The first to third emission layers EML-R, EML-G, and EML-B may have a single layer formed of a single material, a single layer formed of a plurality of different materials, or a multilayer structure having a plurality of layers formed of a plurality of different materials. In an embodiment, the first to third emission layers EML-R, EML-G, and EML-B may include an anthracene derivative, a pyrene derivative, a fluoranthene derivative, a chrysene derivative, a dihydrobenzanthracene derivative, or a triphenylene derivative. However, embodiments of the present inventive concept are not necessarily limited thereto.

For example, the first to third emission layers EML-R, EML-G, and EML-B may include a single host and a single dopant. Alternatively, the first to third emission layers EML-R, EML-G, and EML-B may include two or more hosts and dopants.

In an embodiment, the third emission layer EML-B of the third light emitting element ED-3 emitting blue light may emit thermally activated delayed fluorescence (TADF) or phosphorescence. The third emission layer EML-B of the third light emitting element ED-3 may include a thermally activated delayed fluorescent material and/or a phosphorescent material. The third light emitting element ED-3 including a thermally activated delayed fluorescent material and/or a phosphorescent material may exhibit increased light emitting efficiency.

In an embodiment, the first to third emission layers EML-R, EML-G, and EML-B may include, as a known dopant material, styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and the like.

In an embodiment, the first to third emission layers EML-R, EML-G, and EML-B may include a known phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), or thulium (Tm) may be used. To be specific, iridium(III) bis(4,6-difluorophenylpyridinato-N,C2′)picolinate (FIrpic), bis(2,4-difluorophenylpyridinato)-tetrakis(1-pyrazolyl)borate iridium(III) (FIr6), platinum octaethyl porphyrin (PtOEP), and the like may be used as a phosphorescent dopant. However, embodiments of the present inventive concept are not necessarily limited thereto.

The electron transport region ETR may include at least one of a hole blocking layer, an electron transport layer, or an electron injection layer. The electron transport region ETR may have a single layer formed of a single material, a single layer formed of a plurality of different materials, or a multilayer structure having a plurality of layers formed of a plurality of different materials.

In an embodiment, the electron transport region ETR may include an anthracene-based compound. However, embodiments of the present inventive concept are not necessarily limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or a mixture thereof.

In addition, in an embodiment the electron transport region ETR may include halogenated metals such as LiF, NaCl, CsF, RbCl, RbI, Cul, and KI, lanthanide metals such as Yb, or co-deposition materials of a halogenated metal and a lanthanide metal. For example, the electron transport region ETR may include KI:Yb, RbI:Yb, LiF:Yb, and the like as a co-deposition material. In an embodiment, for the electron transport region ETR, a metal oxide such as Li₂O and BaO, or 8-hydroxyl-lithium quinolate (Liq), and the like may be used. However, embodiments of the present inventive concept are not necessarily limited thereto. The electron transport region ETR may also be formed of a mixture material of an electron transport material and an insulating organo-metal salt. The organo metal salt may be a material having an energy band gap of about 4 eV or greater. For example, the organo-metal salt may include, for example, metal acetates, metal benzoates, metal acetoacetates, metal acetylacetonates, or metal stearates. However, embodiments of the present inventive concept are not necessarily limited thereto.

In an embodiment, the second electrode EL2 may be a common electrode. The second electrode EL2 may be a cathode or an anode. However, embodiments of the present inventive concept are not necessarily limited thereto. For example, in an embodiment in which the first electrode EL1 is an anode, the second electrode EL2 may be a cathode. In an embodiment in which the first electrode EL1 is a cathode, the second electrode EL2 may be an anode. In an embodiment, the second electrode EL2 may include at least one compound selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof. However, embodiments of the present inventive concept are not necessarily limited thereto.

In addition, the first to third light emitting elements ED-1, ED-2, and ED-3 may include a capping layer CPL disposed on the second electrode EL2. The capping layer CPL may be an organic layer or an inorganic layer. For example, in an embodiment in which the capping layer CPL includes an inorganic material, the inorganic material may include an alkali metal compound such as LiF, an alkaline earth metal compound such as MgF₂, SION, SiNₓ, SiO_{y}, and the like. For example, in an embodiment in which the capping layer CPL includes an organic material, the organic material may include α-NPD, NPB, TPD, m-MTDATA, Alq₃, CuPc, N4,N4,N4′, N4′-tetra(biphenyl-4-yl) biphenyl-4,4′-diamine (TPD15), 4,4′,4″-tris(carbazol-9-yl)triphenylamine (TCTA), and the like or may include epoxy resins or acrylates such as methacrylates.

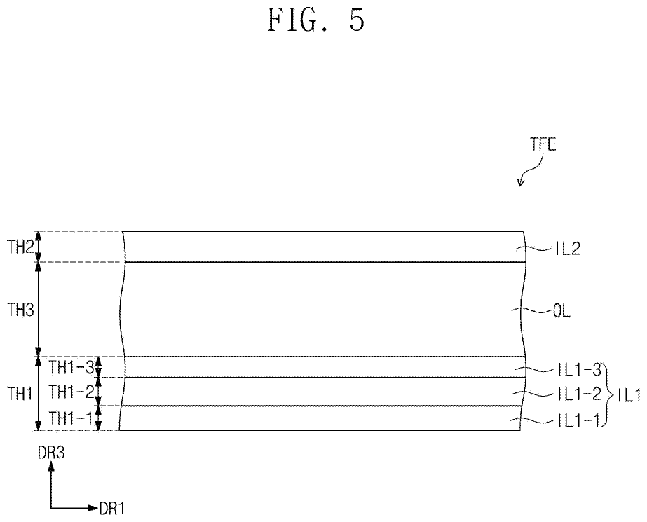

In an embodiment, the encapsulation layer TFE may cover the display element layer DP-ED. The encapsulation layer TFE may be a thin film encapsulation layer. The encapsulation layer TFE may include a first inorganic encapsulation film IL1, an organic encapsulation film OL disposed on the first inorganic encapsulation film IL1, and a second inorganic encapsulation film IL2 disposed on the organic encapsulation film OL. The encapsulation layer TFE will be described in detail later with reference to FIG. 5.

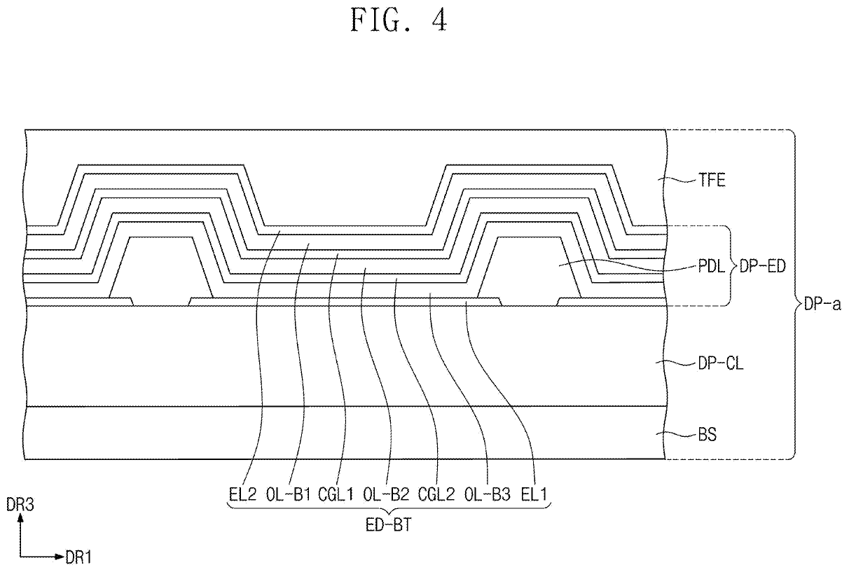

FIG. 4 is a cross-sectional view showing an embodiment of the present inventive concept, and compared to the display panel DP shown in FIG. 3, a display panel DP-a shown in FIG. 4 is different in that the display panel DP-a includes a plurality of light emitting structures, such as first to third light emitting structures OL-B1, OL-B2, and OL-B3. In the description of the display panel according to an embodiment with reference to FIG. 4, duplicated descriptions as one described with reference to FIGS. 1 to 3 may not be given again, and differences will be mainly described for economy of description.

Referring to FIG. 4, in the display device DP-a, a light emitting element ED-BT may include a plurality of light emitting structures, such as first to third light emitting structures OL-B1, OL-B2, and OL-B3. However, embodiments of the present inventive concept are not necessarily limited thereto and the number of the light emitting structures may vary. The light emitting element ED-BT may include the first electrode EL1 and the second electrode EL2 facing each other (e.g., in the third direction DR3), and the first to third plurality of light emitting structures OL-B1, OL-B2, and OL-B3 provided between the first electrode EL1 and the second electrode EL2. The first to third light emitting structures OL-B1, OL-B2, and OL-B3 may be sequentially stacked in the thickness direction DR3 between the first electrode EL1 and the second electrode EL2.

Each of the first to third light emitting structures OL-B1, OL-B2, and OL-B3 may include an emission layer (e.g., any one of the first to third emission layers EML-R, EML-G, and EML-B in FIG. 3) and the hole transport region HTR (FIG. 3) and the electron transport region ETR (FIG. 3) disposed with the emission layer (any one of EML-R, EML-G, and EML-B in FIG. 3) therebetween. For example, the light emitting element ED-BT shown in FIG. 4 may be a light emitting element having a tandem structure including a plurality of emission layers.

In an embodiment, light emitted from each of the first to third light emitting structures OL-B1, OL-B2, and OL-B3 may all be blue light. However, embodiments of the present inventive concept are not necessarily limited thereto, and wavelength ranges of light emitted from each of the first to third light emitting structures OL-B1, OL-B2, and OL-B3 may be different from each other. For example, the light emitting element ED-BT including the plurality of light emitting structures, such as the first to third light emitting structures OL-B1, OL-B2, and OL-B3 may emit light in different wavelength ranges from each other or may each emit white light.

First and second charge generation layers CGL1 and CGL2 may be disposed between adjacent first to third light emitting structures OL-B1, OL-B2, and OL-B3. In an embodiment, the first and second charge generation layers CGL1 and CGL2 may include a p-type charge generation layer and/or an n-type charge generation layer.

FIG. 5 is a cross-sectional view showing an encapsulation layer TFE according to an embodiment. Hereinafter, descriptions of the encapsulation layer TFE may be equally applied to the display panel DP shown in an embodiment of FIG. 4 and the display panel DP-a shown in an embodiment of FIG. 5. In an embodiment, the encapsulation layer TFE may include a first inorganic encapsulation film IL1, an organic encapsulation film OL, and a second inorganic encapsulation film IL2.

The organic encapsulation film OL may protect the light emitting element layer DP-ED from foreign substances such as dust particles. In an embodiment, the organic encapsulation layer OL may have a smaller refractive index than the second inorganic encapsulation layer IL2. Alternatively, the refractive index of the organic encapsulation film OL may be greater than or equal to the refractive index of the second inorganic encapsulation film IL2. In an embodiment, the organic encapsulation film OL may include an acrylic compound, an epoxy-based compound, and the like. The organic encapsulation film OL may include a photopolymerizable organic material. However, embodiments of the present disclosure are not necessarily limited thereto. In an embodiment, a thickness TH3 (e.g., length in the third direction DR3) of the organic encapsulation film OL may be greater than a thickness TH1 (e.g., length in the third direction DR3) of the first inorganic encapsulation film IL1 and a thickness TH2 of the second inorganic encapsulation film IL2. For example, the organic encapsulation layer OL may have a thickness TH3 in a range of about 79000 Å to about 81000 Å. An organic encapsulation film having a thickness of less than about 79000 Å may not sufficiently protect the display element layer DP-ED from foreign substances. In addition, an organic encapsulation film having a thickness of greater than about 81000 Å may reduce the emission of light from the display element layer DP-ED. The organic encapsulation film OL having a thickness TH3 in a range of about 79000 Å to about 81000 Å may exhibit excellent sealing reliability and contribute to maintaining satisfactory display quality.

The first inorganic encapsulation film IL1 may protect the display element layer DP-ED from moisture and/or oxygen. In an embodiment, the refractive index of the first inorganic encapsulation film IL1 may be less than the refractive index of the second inorganic encapsulation film IL2. Alternatively, the refractive index of the first inorganic encapsulation film IL1 may be greater than or equal to the refractive index of the second inorganic encapsulation film IL2. In an embodiment, the first inorganic encapsulation film IL1 may include at least one compound selected from silicon nitride, silicon oxynitride, silicon oxide, titanium oxide, or aluminum oxide. The first inorganic encapsulation layer IL1 may have a thickness TH1 (e.g., length in the third direction DR3) in a range of about 10600 Å to about 11600 Å. A first inorganic encapsulation film having a thickness of less than about 10600 Å may not sufficiently protect the display element layer DP-ED from moisture and oxygen. A first inorganic encapsulation film having a thickness of greater than about 11600 Å reduces emission of light emitted from the display element layer DP-ED. The first inorganic encapsulation film IL1 having a thickness TH1 in a range of about 10600 Å to about 11600 Å may exhibit excellent sealing reliability and contribute to maintaining satisfactory display quality.

Referring to FIG. 5, in an embodiment the first inorganic encapsulation layer IL1 may include a first sub-inorganic encapsulation layer IL1-1, a second sub-inorganic encapsulation layer IL1-2, and a third sub-inorganic encapsulation layer IL1-3, which are sequentially stacked on each other (e.g., in the third direction DR3). In an embodiment, the second sub-inorganic encapsulation layer IL1-2 and the third sub-inorganic encapsulation layer IL1-3 may be formed of silicon oxynitride, and the first sub-inorganic encapsulation layer IL1-1 may be formed of silicon nitride. However, embodiments of the present inventive concept are not necessarily limited thereto and materials forming the first to third sub-inorganic encapsulation layers IL1-1, IL1-2, and IL1-3 may vary.

In an embodiment, a thickness TH1-2 (e.g., length in the third direction DR3) of the second sub-inorganic encapsulation layer IL1-2 may be greater than a thickness TH1-1 (e.g., length in the third direction DR3) of the first sub-inorganic encapsulation layer IL1-1 and a thickness TH1-3 (e.g., length in the third direction DR3) of the third sub-inorganic encapsulation layer IL1-3. The thickness TH1-1 of the first sub-inorganic encapsulation layer IL1-1 may be greater than the thickness TH1-3 of the third sub-inorganic encapsulation layer IL1-3. For example, the thickness TH1-2 of the second sub-inorganic encapsulation layer IL1-2 may be about 9000 Å, the thickness TH1-1 of the first sub-inorganic encapsulation layer IL1-1 may be about 1300 Å, and the thickness TH1-3 of the third sub inorganic encapsulation layer IL1-3 may be about 800 Å. However, embodiments of the present inventive concept are not necessarily limited thereto and the thicknesses TH1-1, TH1-2, and TH1-3 of the first to third sub-inorganic encapsulation layers IL1-1, IL1-2, and IL1-3 may vary.

The second inorganic encapsulation film IL2 may protect the display element layer DP-ED from moisture and/or oxygen. The second inorganic encapsulation layer IL2 may have a thickness TH2 (e.g., length in the third direction DR3) in a range of about 6000 Å to about 8000 Å. A second inorganic encapsulation film having a thickness of less than about 6000 Å may not sufficiently protect the display element layer DP-ED from moisture and oxygen. A second inorganic encapsulation film having a thickness of greater than about 8000 Å reduces emission of light emitted from the display element layer DP-ED. The second inorganic encapsulation film IL2 having a thickness TH2 in a range of about 6000 Å to about 8000 Å may exhibit excellent sealing reliability and contribute to maintaining satisfactory display quality.

In an embodiment, the second inorganic encapsulation film IL2 may have a refractive index in a range of about 1.89 to about 2.20. The second inorganic encapsulation film IL2 may include silicon nitride. In an embodiment, a display panel DP including the second inorganic encapsulation film IL2 having a refractive index in a range of about 1.89 to about 2.20 may exhibit an excellent display lifetime.

For example, the second inorganic encapsulation film IL2 may have a refractive index in a range of about 1.89 to about 2.20 at a wavelength of about 459 nm. For example, the second inorganic encapsulation film IL2 may have a refractive index in a range of about 1.89 to about 2.14 at a wavelength of about 459 nm. In an embodiment in which the forming an encapsulation film is performed by providing the same material, the refractive index may be regulated by applying different process conditions. For example, the first and second inorganic encapsulation films IL1 and IL2 may be formed through chemical vapor deposition (CVD). In an embodiment in which the forming an encapsulation film is performed by providing the same material, the refractive index of an encapsulation film may be regulated by changing deposition conditions (e.g., pressure, material ratio, and the like).

The wavelength of 459 nm corresponds to a blue wavelength range. The blue light emitted from the light emitting element (e.g., the third light emitting element ED-3) may release hydrogen atoms constituting the silicon nitride of the second inorganic encapsulation layer IL2. In the silicon nitride, hydrogen atoms bonded to nitrogen atoms and/or hydrogen atoms bonded to silicon atoms may be released. The second inorganic encapsulation layer IL2 in which hydrogen atoms are released from the silicon nitride may have increased transmittance for light. The second inorganic encapsulation film IL2 has a high refractive index in a range of about 1.89 to about 2.20, and may have a greater change in transmittance for light than an inorganic encapsulation film having a relatively lower refractive index. Accordingly, when the same current is applied to a light emitting element (e.g., the third light emitting element ED-3), the light efficiency is increased compared to a second inorganic encapsulation film IL2 having a relatively lower refractive index and an overshoot of lifetime may take place, which may provide an increase in the display lifetime of the display panel DP.

In an embodiment, the display device may not include a polarizing plate. The display device DD according to an embodiment without a polarizing plate may exhibit an increased display lifetime. An amount of blue light reflected back to an encapsulation layer after being emitted from the light emitting element may be greater in the display device DD without a polarizing plate than in the display device including a polarizing plate. Accordingly, the display device DD without a polarizing plate has a greater increase in light transmittance of the second inorganic encapsulation film IL2 due to blue light, and may thus exhibit an increased display lifetime.

Hereinafter, with reference to Examples and Comparative Examples, an encapsulation layer according to an embodiment of the present inventive concept and a display panel including the encapsulation layer will be specifically described. In addition, Examples shown below are shown only for the understanding of embodiments of the present inventive concept, and the scope of the present inventive concept is not necessarily limited thereto.

### Examples

In the evaluation of Comparative Examples and Examples described below with reference to drawings and tables, CAS140CT from Instrument Systems was used. Hereinafter, a display panel of Examples include a first sub-inorganic encapsulation layer having a thickness of about 1300 Å, a second sub-inorganic encapsulation layer having a thickness of about 9000 Å, a third sub-inorganic encapsulation layer having a thickness of about 800 Å, an organic encapsulation film having a thickness of about 80000 Å, and a second sub-inorganic encapsulation layer having a thickness of about 7000 Å. In the display panel of Examples, the first sub-inorganic encapsulation layer is formed of silicon nitride, and the second and third sub-inorganic encapsulation layers are formed of silicon oxynitride. The second sub-inorganic encapsulation layer has a refractive index of about 1.62, and the third sub-inorganic encapsulation layer has a refractive index of about 1.57. In addition, only a refractive index of the second inorganic encapsulation film is different between Examples and Comparative Examples, and other components are the same.

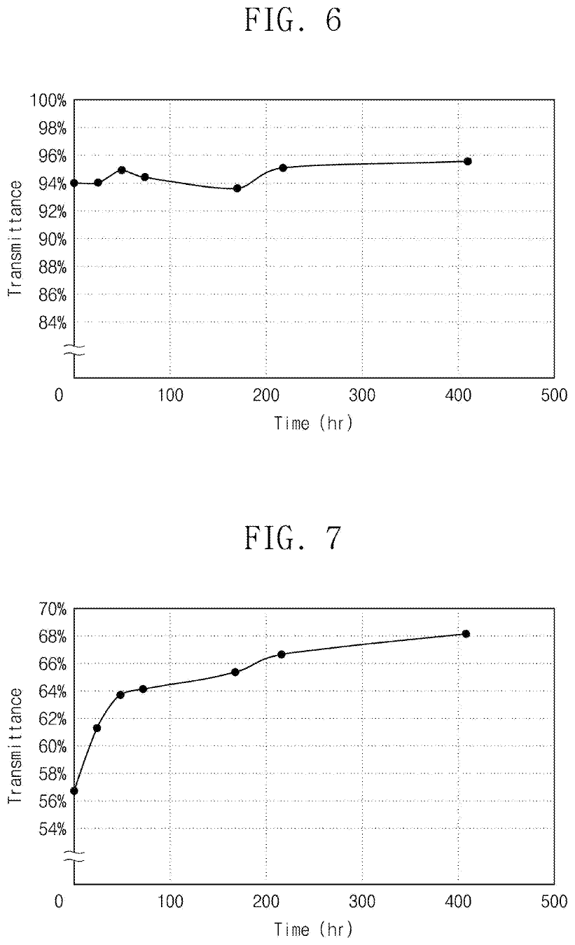

FIG. 6 is a graph showing light transmittance over time in the display panel of Comparative Example 1, and FIG. 7 is a graph showing light transmittance over time in the display panel of Example 2. FIGS. 6 and 7 are the results obtained after determining light transmittance over time by providing light having a wavelength of about 459 nm to the display panels of Comparative Example 1 and Example 1. The display panel of Example 1 provided in the evaluation of FIG. 7 is a display panel according to an embodiment of the present inventive concept, and includes a second inorganic encapsulation film formed of silicon nitride and having a refractive index of about 2.14. For example, the display panel of Example 1 provided in the evaluation of FIG. 7 includes the second inorganic encapsulation film satisfying the refractive index range according to an embodiment of the present inventive concept. The display panel of Comparative Example 1 provided in the evaluation of FIG. 6 has the same components as the display panel of Example 1, except that the second inorganic encapsulation film formed of silicon nitride has a refractive index of about 1.88 which is outside (e.g., below) the refractive index range according to an embodiment of the present inventive concept.

Referring to FIG. 6, it is seen that the display panel of Comparative Example 1 has a relatively small change in transmittance over time. In FIG. 6, it is seen that the change in transmittance is less than about 2%. Referring to FIG. 7, it is seen that the display panel of Example 1 has a relatively large change in transmittance over time. For example, in FIG. 7, it is that the change in transmittance is about 10% or greater from about a 57% light transmittance at 0 hours to about a 68% light transmittance at 400 hours, which is over a 19% increase in light transmittance. The display panel of Example 1 includes the second inorganic encapsulation film having a relatively high refractive index, and it is seen that the change in transmittance due to blue light is large. When the same current is applied to the display panel of Comparative Example 1 and the display panel of Example 1, the display panel of Example 1, which has a relatively large change in transmittance of over 10% may exhibit a relatively large increase in lifetime. Accordingly, in an embodiment, a display panel including the second inorganic encapsulation film having a relatively high refractive index may exhibit an increased display lifetime.

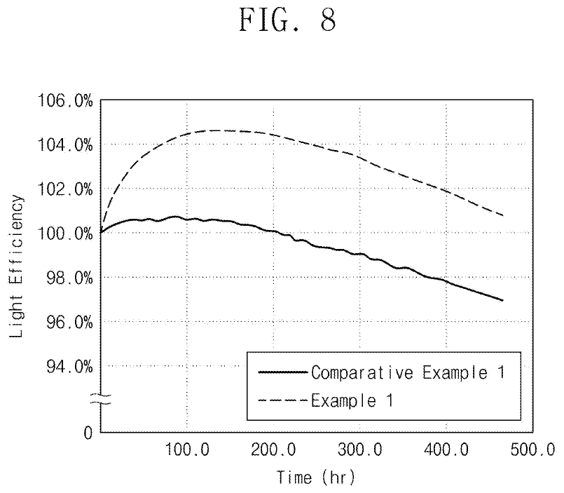

FIG. 8 is a graph showing light efficiency over time in the display panels of Comparative Example 1 and Example 1, and is an evaluation result in which blue light is provided. Light efficiency is a relative value obtained by measuring luminance (cd/A) according to current and setting an initial value as 100%. The display panel of Comparative Example 1 is the display panel of Comparative Example 1 provided in the evaluation of FIG. 6, and the display panel of Example 1 is the display panel of Example 1 provided in the evaluation of FIG. 7.

Referring to FIG. 8, it is seen that compared to the display panel of Comparative Example 1, the display panel of Example 1 exhibits relatively high light efficiency. In the display panel of Example 1, an overshoot of lifetime between 0 hours and 100 hours is observed in which light efficiency increases from about 100.0% to about 104.0%. In addition, it is seen that the display panel of Example 1 has an excellent (e.g., an increased) display lifetime through the fact that the light efficiency increase due to the overshoot is maintained even after 100 hours. For example, compared to the display panel of Comparative Example 1, the display panel of Example 1, which exhibits relatively high light efficiency over time, may exhibit an increased display lifetime.

Table 1 below shows the evaluation of lifetime (T93) for blue light in the display panels of Comparative Example 1, Example 1, and Examples A1 to A5. The display panel of Comparative Example 1 is the display panel of Comparative Example 1 provided in the evaluation of FIG. 6, and the display panel of Example 1 is the display panel of Example 1 provided in the evaluation of FIG. 7 according to an embodiment of the present inventive concept. The display panels of Examples A1 to A5 are display panels according to an embodiment of the present inventive concept, and in the display panels, the second inorganic encapsulation film has a refractive index in the range of about 1.89 to about 2.20. The results of the display panels of Examples A1 to A5 are simulation results, and the evaluation results of the display panels of Comparative Example 1 and Example 1 are results obtained through direct measurement.

In Table 1, the term “refractive index” indicates a refractive index of the second inorganic encapsulation film. The term “lifetime” and T93 indicates the time taken (in hours) to decrease from an initial luminance of 100% to a luminance of 93%, and the term “lifetime increase” shows a difference in lifetime with respect to the life measured in Comparative Example 1. The term “improvement rate” shows the rate of increase in lifetime with respect to the life measured in Comparative Example 1.

TABLE 1

| | Refractive | Lifetime(T93) | Lifetime | Improvement |
|---|---|---|---|---|
| | index | (in hours) | increase | rate |
| Comparative | 1.879 | 830 | 0 | 0% |
| Example 1 | | | | |
| Example A1 | 1.942 | 887 | 57 | 6.9% |
| Example A2 | 1.979 | 921 | 91 | 11.0% |
| Example A3 | 2.007 | 946 | 116 | 14.0% |
| Example A4 | 2.028 | 965 | 135 | 16.3% |
| Example A5 | 2.07 | 1003 | 173 | 20.8% |
| Example 1 | 2.14 | 1067 | 237 | 28.6% |

Referring to Table 1, it is seen that, compared to the display panel of Comparative Example 1, the display panels of Example 1 and Examples A1 to A5 exhibit an excellent (e.g., increased) display lifetime. In addition, referring to the improvement rates of the display panels of Examples A1 to A5 and Example 1, it is seen that when the refractive index is higher, the improvement rate in lifetime is greater. The display panels of Examples 1 and A1 to A5 include the second inorganic encapsulation film having the refractive index range according to an embodiment of the present inventive concept. Accordingly, in an embodiment, a display panel including the second inorganic encapsulation film having a refractive index of about 1.89 to about 2.20 may exhibit an increased display lifetime.

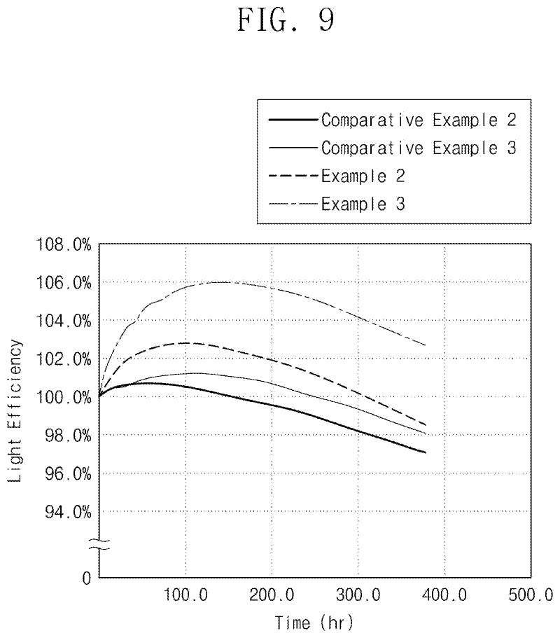

FIG. 9 is a graph showing light efficiency over time in the display devices of Comparative Example 2, Comparative Example 3, Example 2, and Example 3, and is an evaluation result in which blue light is provided. In FIG. 9, light efficiency is a relative value obtained by measuring luminance (cd/A) versus current and setting an initial value as 100%.

The display devices of Examples 2 and 3 are display devices according to an embodiment of the present inventive concept, and include a second inorganic encapsulation film formed of silicon nitride and having a refractive index of about 2.14. Example 2 is a display device including a polarizing plate, and Example 3 is a display device without a polarizing plate. The display device of Comparative Example 2 includes the same components as Example 2, except that the second inorganic encapsulation film formed of silicon nitride has a refractive index of about 1.88 which is outside the refractive index range. The display device of Comparative Example 3 includes the same components as Example 3, except that the second inorganic encapsulation film formed of silicon nitride has a refractive index of about 1.88 which is outside the refractive index range. For example, the display device of Comparative Example 2 includes a polarizing plate, and the display device of Comparative Example 3 does not include a polarizing plate.

In FIG. 9, comparing the display devices of Comparative Example 2 and Example 2, which include a polarizing plate, it is seen that the display device of Example 2 including the second inorganic encapsulation film having a relatively high refractive index exhibits high light efficiency. Compared to the display device of Comparative Example 2, as the display device of Example 2 exhibits relatively high light efficiency, it is seen that the display device of Example 2 exhibits an excellent (e.g., increased) display lifetime.

In FIG. 9, comparing the display devices of Comparative Example 3 and Example 3, which do not include a polarizing plate, it is seen that the display device of Example 3 including the second inorganic encapsulation film having a relatively high refractive index exhibits high light efficiency. Compared to the display device of Comparative Example 3, as the display device of Example 3 exhibits relatively high light efficiency, it is seen that the display device of Example 3 exhibits an increased display lifetime.

In addition, in FIG. 9, it is seen that the display device of Example 3 including the second inorganic encapsulation film that does not include a polarizing plate and satisfies the refractive index range according to an embodiment exhibits relatively high light efficiency as compared to Example 2 that includes a polarizing plate. Accordingly, a display device according to an embodiment including a second inorganic encapsulation film having a refractive index in a range of about 1.89 to about 2.14 without a polarizing plate may exhibit an excellent (e.g., increased) display lifetime.

FIGS. 10 and 11 show the measured color coordinates (White_x, White_y) of white in the display panels of Comparative Example 4 and Example 4, with respect to the CIE 1931 color space. In the evaluation of FIGS. 10 and 11, a plurality of display panels of Comparative Example 4 and Example 4 were provided and evaluated at a position of 45° with respect to a front. FIGS. 10 and 11 are data for determining white angle dependency (WAD) according to viewing angles.

The display panel of Example 4 is a display panel according to an embodiment, and includes a second inorganic encapsulation film formed of silicon nitride and having a refractive index of about 1.94. The display panel of Comparative Example 4 includes the same components as the display panel of Example 4, except that the second inorganic encapsulation film formed of silicon nitride has a refractive index of about 1.88.

In FIGS. 10 and 11, a circle indicated as L_1 shows a region where Δu′v′ is 0.01, and a display panel in which Δu′v′ is 0.01 is determined to have excellent (e.g., increased) display quality. In addition, in FIGS. 10 and 11, Ta_x and Ta_y indicate desired white color coordinates, and a display panel satisfying the color coordinates is determined to have excellent (e.g., increased) display quality.

Referring to FIGS. 10 and 11, it is seen that the display panel of Comparative Example 4 and the display panel of Example 4 have similar levels of white angle dependency (WAD) according to viewing angles. For example, it is seen that Comparative Example 4 and Example 4 have a similar level of display quality.

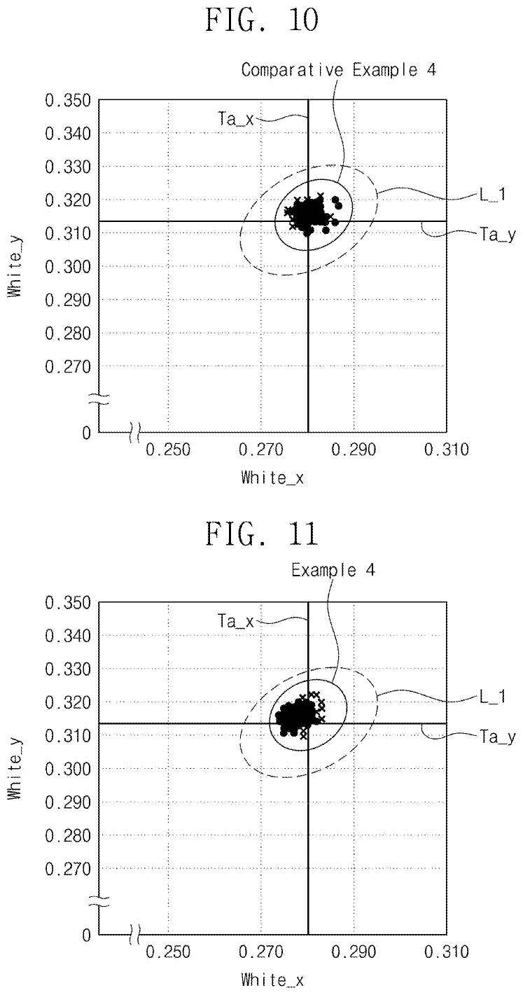

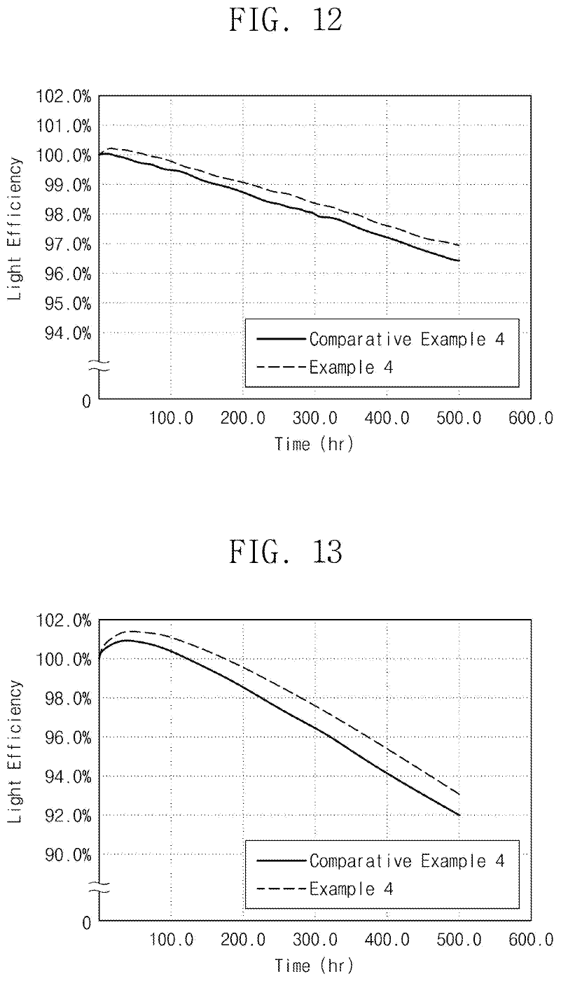

FIG. 12 is a graph showing light efficiency over time in the display panels of Comparative Example 4 and Example 4, and is an evaluation result in which white light is provided. In FIG. 12, light efficiency is a relative value obtained by measuring luminance (cd/A) versus current and setting an initial value as 100%.

Referring to FIG. 12, it is seen that compared to the display panel of Comparative Example 4, the display panel of Example 4 exhibits relatively high light efficiency. It is seen that the display panel of Example 4 exhibits high light efficiency over time and thus has an excellent (e.g., increased) display lifetime. Accordingly, in an embodiment, a display panel including the second inorganic encapsulation film having a refractive index of about 1.89 to about 2.20 may exhibit an increased display lifetime.

FIG. 13 is a graph showing light efficiency over time in the display panels of Comparative Example 4 and Example 4, and is an evaluation result in which blue light is provided. Light efficiency is a relative value obtained by measuring luminance (cd/A) according to current and setting an initial value as 100%.

Referring to FIG. 13, it is seen that compared to the display panel of Comparative Example 4, the display panel of Example 4 exhibits relatively high light efficiency. It is seen that the display panel of Example 4 exhibits high light efficiency over time and thus has an excellent display lifetime. Accordingly, in an embodiment, a display panel including the second inorganic encapsulation film having a refractive index in a range of about 1.89 to about 2.20 may exhibit an increased display lifetime.

Table 2 below shows the evaluation of lifetime in the display panels of Comparative Example 4 and Example 4 described above. The term “lifetime” indicates the time taken to decrease from an initial luminance of 100% to a luminance of 93%, and “White light, lifetime” is an evaluation of the lifetime when white light is provided, and “blue light, lifetime” is an evaluation of the lifetime when blue light is provided.

TABLE 2

| | Refractive | White light, lifetime | blue light, lifetime |
|---|---|---|---|
| | index | (hr) | (hr) |
| Example 4 | 1.94 | 1016 | 533 |
| Comparative | 1.88 | 926 | 458 |
| Example 4 | | | |

In Table 2, when white light is provided, the lifetime improvement rate of Example 4 is about 10% with respect to Comparative Example 4. When blue light is provided, the lifetime improvement rate of Example 4 is about 16% with respect to Comparative Example 4. Example 4 includes a second inorganic encapsulation film having the refractive index range according to an embodiment of the present inventive concept. Accordingly, in an embodiment, a display panel including the second inorganic encapsulation film having a refractive index in a range of about 1.89 to about 2.20 may exhibit an increased display lifetime.

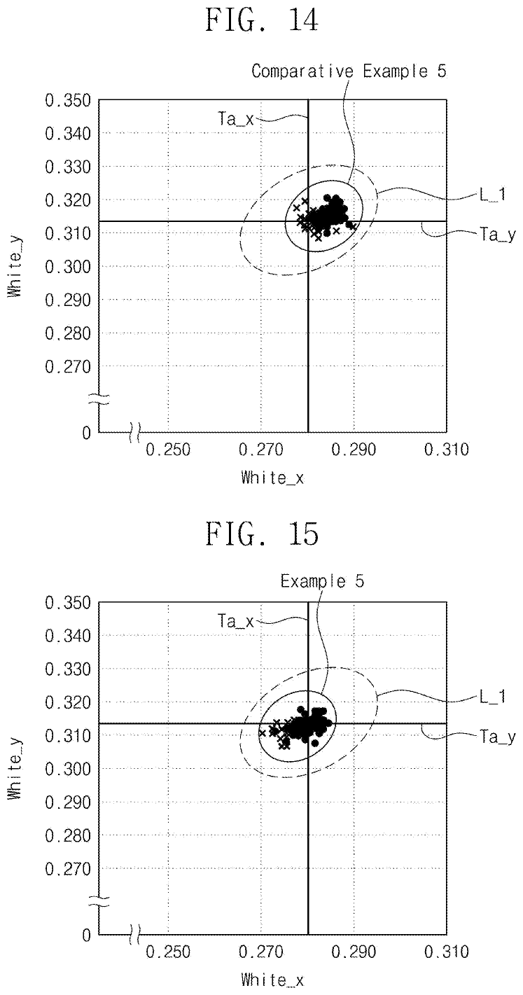

FIGS. 14 and 15 show the measured color coordinates (White_x, White_y) of white in the display panels of Comparative Example 5 and Example 5, with respect to the CIE 1931 color space. In the evaluation of FIGS. 14 and 15, a plurality of display panels of Comparative Example 5 and Example 5 were provided and evaluated at a position of 45° with respect to a front. FIGS. 14 and 15 are data for determining white angle dependency (WAD) according to viewing angles.

The display panel of Example 5 is a display panel according to an embodiment, and includes a second inorganic encapsulation film formed of silicon nitride and having a refractive index of about 2.14. The display panel of Comparative Example 5 includes the same components as the display panel of Example 5, except that the second inorganic encapsulation film formed of silicon nitride has a refractive index of about 1.88 which is outside the refractive index range.

In FIGS. 14 and 15, a circle indicated as L_1 shows a region where Δu′v′ is 0.01, and a display panel in which Δu′v′ is 0.01 is determined to have excellent display quality. In addition, in FIGS. 14 and 15, Ta_x and Ta_y indicate desired white color coordinates, and a display panel satisfying the color coordinates is determined to have excellent display quality.

Referring to FIGS. 14 and 15, it is seen that the display panel of Comparative Example 5 and the display panel of Example 5 have similar levels of white angle dependency (WAD) according to viewing angles. For example, it is seen that Comparative Example 5 and Example 5 have a similar level of display quality.

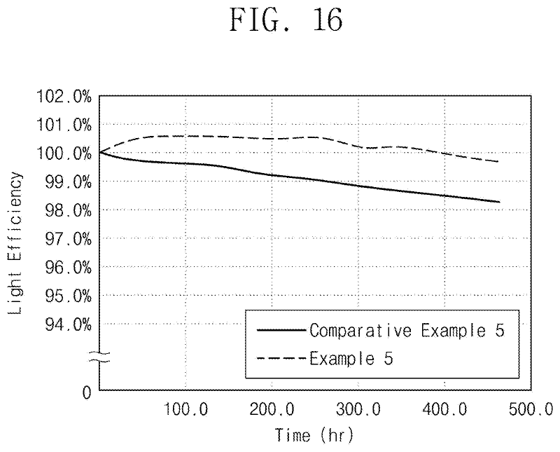

FIG. 16 is a graph showing light efficiency over time in the display panels of Comparative Example 5 and Example 5, and is an evaluation result in which white light is provided. Light efficiency is a relative value obtained by measuring luminance (cd/A) versus current and setting an initial value as 100%.

Referring to FIG. 16, it is seen that compared to the display panel of Comparative Example 5, the display panel of Example 5 exhibits relatively high light efficiency. It is seen that the display panel of Example 5 exhibits high light efficiency over time and thus has an excellent display lifetime. For example, compared to the display panel of Comparative Example 5, the display panel of Example 5, which exhibits relatively high light efficiency over time, may exhibit an increased display lifetime.

Table 3 below shows the evaluation of lifetime in the display panels of Comparative Example 5 and Example 5. The term “lifetime” indicates the time taken to decrease from an initial luminance of 100% to a luminance of 93%, and the lifetime is evaluated when white light is provided.

TABLE 3

| | | White light, lifetime |
|---|---|---|
| | Refractive index | (hr) |
| Example 5 | 2.14 | 2016 |
| Comparative | 1.88 | 1626 |
| Example 5 | | |

In Table 3, the lifetime improvement rate of Example 5 is about 24% with respect to Comparative Example 5. Example 5 includes a second inorganic encapsulation film having the refractive index range according to an embodiment of the present inventive concept. Accordingly, in an embodiment, a display panel including the second inorganic encapsulation film having a refractive index in a range of about 1.89 to about 2.20 may exhibit an excellent display lifetime.

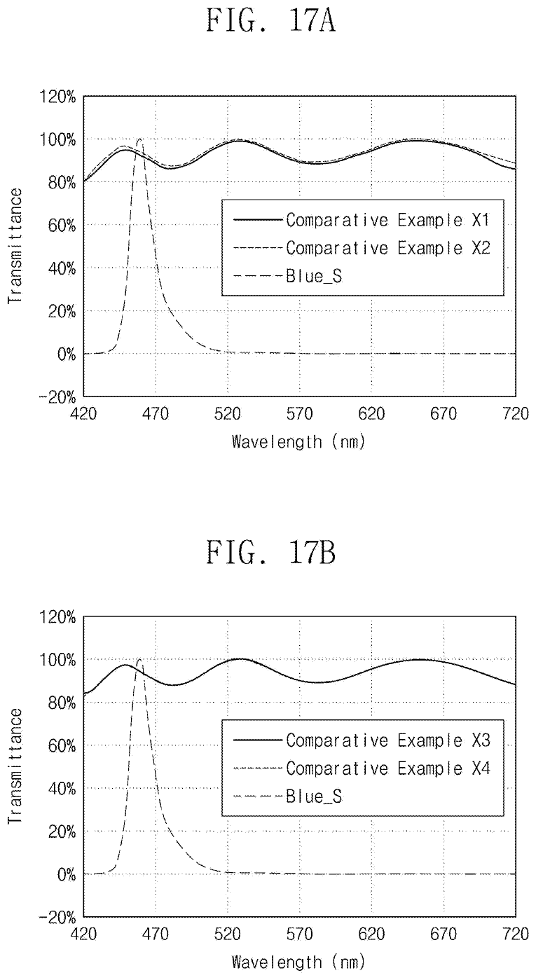

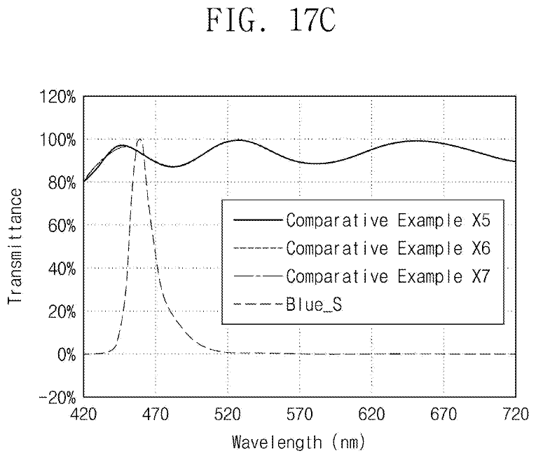

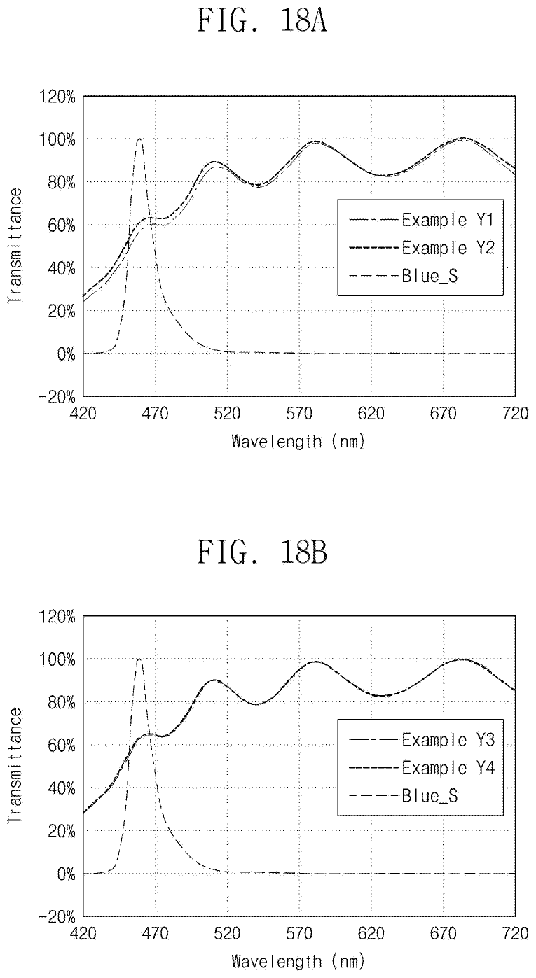

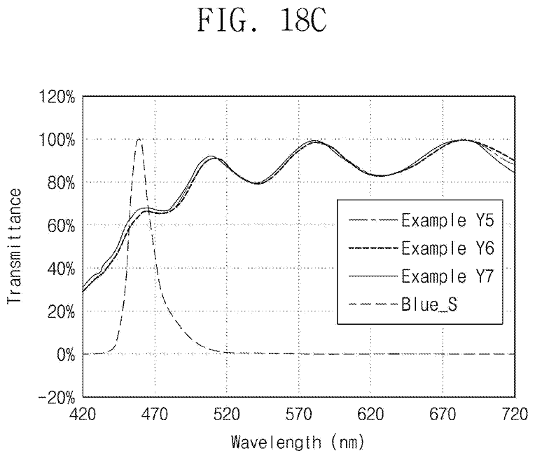

FIGS. 17A to 17C are graphs showing light transmittance versus wavelength in display panels of Comparative Examples X1 to X7 including a second inorganic encapsulation film having a refractive index of about 1.88 outside of the refractive index range. FIGS. 18A to 18C are graphs showing transmittance versus wavelength in display panels of Examples Y1 to Y7 including a second inorganic encapsulation film having a refractive index of about 2.14 within the refractive index range. In FIGS. 17A to 17C and 18A to 18C, Blue_S corresponds to a wavelength range of blue light. In Comparative Examples X1 to X7, the blue light is provided for a different time period, and the blue light was provided for a relatively longer period of time from Comparative Examples X1 to X7. In Examples Y1 to Y7, the blue light is provided for a different time period, and the blue light was provided for a relatively longer period of time from Example Y1 to Y7.

Comparative Example X1 and Example Y1 were measured 0 hours after the irradiation with blue light, that is, immediately after the irradiation with blue light. Comparative Example X2 and Example Y2 were measured 24 hours after the irradiation with blue light. Comparative Example X3 and Example Y3 were measured 48 hours after the irradiation with blue light. Comparative Example X4 and Example Y4 were measured 72 hours after the irradiation with blue light. Comparative Example X5 and Example Y5 were measured 168 hours after the irradiation with blue light. Comparative Example X6 and Example Y6 were measured 216 hours after the irradiation with blue light. Comparative Example X7 and Example Y7 were measured 408 hours after the irradiation with blue light.

Referring to FIGS. 17A to 17C, it is seen that Comparative Examples X1 to X7 have similar levels of transmittance for blue light. For example, it is seen that Comparative Examples X1 to X7 including the second inorganic encapsulation film having a relatively low refractive index show a similar level of transmittance over time.

Referring to FIGS. 18A to 18C, it is seen that the transmittance for blue light increases toward Examples Y7 from Y1. Comparing Example Y1 with Example Y7, it is seen that the light transmittance for blue light is greater in Example Y7. For example, it is seen that in Examples Y1 to Y7 including the second inorganic encapsulation film having a relatively high refractive index, the transmittance for blue light is increased over time. Accordingly, in an embodiment, a display panel including the second inorganic encapsulation film having a refractive index in range of about 1.89 to about 2.20 may exhibit an increased display lifetime.

A display device of an embodiment may include a display panel according to an embodiment of the present inventive concept. The display panel of an embodiment may include a display element layer and an encapsulation layer disposed on the display element layer. The encapsulation layer may include a first inorganic encapsulation film, an organic encapsulation film, and a second inorganic encapsulation film, which are sequentially stacked (e.g., in the third direction DR3). The second inorganic encapsulation film may be formed of silicon nitride and have a refractive index in a range of about 1.89 to about 2.20. Accordingly, a display panel including the second inorganic encapsulation film may exhibit an increased display lifetime.

A display panel of an embodiment and a display device including the display panel include an inorganic encapsulation film having a relatively high refractive index, and may thus exhibit an increased display lifetime.

Although the present inventive concept has been described with reference to non-limiting embodiments, it will be understood that the present inventive concept should not be limited to the described embodiments but various changes and modifications can be made by those skilled in the art without departing from the spirit and scope of the present inventive concept.

Accordingly, the present inventive concept is not intended to be limited to the contents set forth in the described embodiments.

What is claimed is:

1. A display panel comprising:
a display element layer including a pixel defining film having a pixel opening defined therein, and a light emitting element; and
an encapsulation layer disposed on the display element layer,
wherein the encapsulation layer includes:
a first inorganic encapsulation film;
an organic encapsulation film disposed on the first inorganic encapsulation film; and
a second inorganic encapsulation film disposed on the organic encapsulation film, the second inorganic encapsulation film has a refractive index in a range of about 1.89 to about 2.20.

2. The display panel of claim 1, wherein the second inorganic encapsulation film comprises silicon nitride.

3. The display panel of claim 1, wherein the first inorganic encapsulation film comprises at least one compound selected from silicon nitride, silicon oxynitride, silicon oxide, titanium oxide, and aluminum oxide.

4. The display panel of claim 1, wherein the second inorganic encapsulation film has a thickness in a range of about 6000 Å to about 8000 Å.

5. The display panel of claim 1, wherein the first inorganic encapsulation film has a thickness in a range of about 10600 Å to about 11600 Å.

6. The display panel of claim 1, wherein the organic encapsulation film has a thickness in a range of about 79000 Å to about 81000 Å.

7. The display panel of claim 1, wherein a thickness of the organic encapsulation film is greater than thicknesses of the first inorganic encapsulation film and the second inorganic encapsulation film.

8. The display panel of claim 1, wherein:
the first inorganic encapsulation film comprises a first sub-inorganic encapsulation layer, a second sub-inorganic encapsulation layer, and a third sub-inorganic encapsulation layer, that are sequentially stacked, and
a thickness of the second sub-inorganic encapsulation layer is greater than thicknesses of the first sub-inorganic encapsulation layer and the third sub-inorganic encapsulation layer.

9. The display panel of claim 1, wherein the encapsulation layer covers the display element layer.

10. The display panel of claim 1, wherein the light emitting element comprises a first electrode exposed in the pixel opening, a second electrode disposed on the first electrode, and an emission layer disposed between the first electrode and the second electrode, and
the light emitting element emits blue light or white light.

11. The display panel of claim 10, wherein the emission layer emits thermally activated delayed fluorescence or phosphorescence.

12. The display panel of claim 10, wherein:
the light emitting element further comprises a hole transport region disposed between the first electrode and the emission layer; and
an electron transport region disposed between the emission layer and the second electrode.

13. A display device comprising:
a display panel; and
a protection member disposed on the display panel,
wherein the display panel includes:
a display element layer including a pixel defining film having a pixel opening defined therein, and a light emitting element; and
an encapsulation layer disposed on the display element layer,
the encapsulation layer including:
a first inorganic encapsulation film;
an organic encapsulation film disposed on the first inorganic encapsulation film; and
a second inorganic encapsulation film disposed on the organic encapsulation film, the second inorganic encapsulation film has a refractive index in a range of about 1.89 to about 2.20.

14. The display device of claim 13, wherein the second inorganic encapsulation film comprises silicon nitride.

15. The display device of claim 13, wherein the display device does not include a polarizing plate.

16. The display device of claim 13, wherein the first inorganic encapsulation film comprises at least one compound selected from silicon nitride, silicon oxynitride, silicon oxide, titanium oxide, and aluminum oxide.

17. The display device of claim 13, wherein the second inorganic encapsulation film has a thickness in a range of about 6000 Å to about 8000 Å.

18. The display device of claim 13, wherein the first inorganic encapsulation film has a thickness in a range of about 10600 Å to about 11600 Å.

19. The display device of claim 13, wherein the organic encapsulation film has a thickness in a range of about 79000 Å to about 81000 Å.

20. The display device of claim 13, wherein:
the display element layer comprises a first light emitting element, a second light emitting element, and a third light emitting element that are spaced apart from each other in a first direction perpendicular to a thickness direction; and
the first light emitting element emits red light, the second light emitting element emits green light, and the third light emitting element emits blue light.
